(19) United States
(12) Patent Application Publication
(10) Pub. No.: US 2003/0082905 A1
(43) Pub. Date: May 1, 2003

(54) Method for forming a uniform damascene profile

(76) Inventors: Jen-Ku Hung, Tainan City (TW); Gow-Wei Sun, Hsin-Chuang City (TW)

Correspondence Address: POWELL, GOLDSTEIN, FRAZER & MURPHY LLP, P.O. BOX 97223, WASHINGTON, DC, 20090-7223, US

(21) Appl. No.: 10/117,039

(22) Filed: Apr. 8, 2002

Related U.S. Application Data
(60) Provisional application No. 60/336,467, filed on Oct. 31, 2001.

(51) Int. Cl. H01L 21/4763

(52) U.S. Cl. 438/633

(57) ABSTRACT

A method for forming a uniform damascene profile is provided. A wet etching process using a mixture containing ionized water, hydrochloric acid and hydrofluoric acid as an etching solution is applied on a substrate having a single/dual damascene structure formed thereon. The etching solution of the mixture containing ionized water, hydrochloric acid and hydrofluoric acid creates an etch selectivity between various layers of the single/dual damascene structure approximately 1:1. Thus, a damascene structure with a good profile is obtained.

### BACKGROUND OF THE INVENTION

1. Field of the Invention

The present invention relates to an interconnect structure, and more particularly to a damascene structure with improved profile.

2. Description of the Prior Art

In a high performance integrated circuit in the sub-0.25 um regime, there is a need to fabricate interconnects using so-called damascene techniques. This is because conventional deposition and etching of aluminum-based metallization becomes increasingly difficult at these feature sizes. At the same time, performance considerations call for the use of lower resistive metals such as copper, which has proven virtually impossible to pattern using conventional reactive ion etching. The desire to use copper for interconnects has increased the attractiveness of damascene techniques and spurred investigation into improving these techniques.

In addition to using low resistive metals such as copper, circuit performance enhancement has been sought by combining the copper conductors with low dielectric constant insulators (k less than approximately 4). In many cases, these low k materials are spin coated polymers which are incompatible with conventional photoresist stripping using oxygen ashers or solvents. The patterning of the low k materials to form the trenches and vias of a damascene formation is a difficult task due to the incompatibility of the low k materials with conventional photoresist stripping.

An example of a single damascene process using low k dielectric material is depicted in FIG. 1A through FIG. 1D. In FIG. 1A, a passivatioin layer 12 is deposited on an interconnect layer 10 having a plurality of conductors 11 formed therein prior to a low k dielectric material such as benzocyclobutene (BCB), hydrogen silsesquioxane (HSQ) or FLARE spun thereon. The passivation layer 12 is normally used to protect the pre-existing interconnect layer from oxidation or corrosion during dry etching. A low k dielectric layer 13 is spun on the passivation layer 12. A cap layer 14 is then deposited on the low k dielectric layer 13. The cap layer 14 may be a TEOS-oxide layer, or a multiple-layer cap layer. For example, the multiple-layer cap layer may have a bottom TEOS-oxide layer, a middle nitride layer and a top layer that is an organic bottom anti-reflective coating (BARC). A photoresist layer 15 is then deposited thereon. The photoresist layer 15 is then patterned with the desired pattern and after development, the cap layer 14 is etched. The etching recipe for the cap layer 14 is different from that of the low k dielectric layer 13, which is an organic etching.

The photoresist layer 15 is then stripped off, using an appropriate oxygen ashing and/or solvent technique. This results in the structure of FIG. 1B. The cap layer 14 is used as a hard mask to pattern the low k dielectric layer 13 and the passivation layer 12 to form the single damascene structure having a trench 16 formed therein. The cap layer 14 is then stripped. This results in the structure of FIG. 1C. However, in the formation of the single damascene structure, an etching process, for cap layer 14, low k dielectric layer 13 and passivation layer 12 is performed. During this etching process polymer residues 17 are produced and left on the surrounding area of trench 16. A wet etching process using a mixture containing ionized water (H₂O) and hydrofluoric acid (HF) is applied on the whole structure to remove the polymer residues 17. As shown in FIG. 1D, the single damascene structure has a poor profile. This is a result of the different etching selectivity between the passivation layer 12 and the low k dielectric layer 13. The poor damascene profile would disadvantageously influence the deposition of a conductive seed layer, such as a copper seed layer. This results in a discontinued conductive seed layer and voids formed on the single damascene structure. The quality of semiconductor devices thus cannot be controlled.

An example of a dual damascene process sequence using a low k dielectric material, having trenches with underlying via holes that are etched in the low k dielectric material before metal deposition and chemical mechanical polishing (CMP), is depicted in FIGS. 2A-2D. This commonly used method of forming the trenches together with the via holes employs etch stop layers and photoresist masks. A passivation layer 22, such as silicon nitride, has been deposited over a conductor 21, such as copper, formed in an interconnect layer 20. A first low k dielectric layer 23 is then deposited on the passivation layer 22. The via will be formed within the first low k dielectric layer 23.

A stop layer 24, such as silicon dioxide, is deposited over the first low k dielectric layer 23. A via pattern 25 is etched into the stop layer 24 using conventional photolithography and appropriate anisotropic dry etching techniques. These steps are not depicted in FIG. 2A. Only the resultant via pattern 25 is depicted in FIG. 2A. The photoresist used in the via patterning is removed by an oxygen plasma.

FIG. 2B depicts the structure of FIG. 2A after a second low k dielectric layer 26 has been spin coated on the stop layer 24 and through the via pattern 25. The structure is planarized at the same time. Following the spin coating and the planarization of the second low k dielectric layer 26 in which the trench will be formed, a hard mask 27 is deposited. The hard mask 27 may be silicon dioxide, for example.

The trench pattern is then formed in a photoresist layer (not depicted) which is aligned over the via pattern 25, using conventional photolithography. The structure is then exposed to an anisotropic dry etch configured to etch through the hard mask 27. The etch chemistry is then changed to one which selectively etches the second low k dielectric layer 26 and the first low k dielectric layer 23, but not the hard mask layer 27 nor the stop layer 24 and the passivation layer 22. In this way, a trench 28 and a via 29 are formed in the same etching process.

In most cases, the low k etch chemistry etches the photoresist at approximately the same rate as the low k dielectric material. The thickness of the trench photoresist is selected to be completely consumed by the end of the etch operation, to eliminate the need for photoresist stripping. This results in the structure depicted in FIG. 2C, in which all of the photoresist has been stripped and the trench 28 and via 29 have been formed. The passivation layer 22 is then removed by a different selective dry etch chemistry designed not to attack any other layers in order to expose the conductor 21 to which the via makes a connection. The resulting structure is depicted in FIG. 2C. As the above-mentioned single damascene process, during various etching processes for forming the dual damascene structure with the trench 28 and the via 29 formed therein, there are polymer residues 200 produced and left on the surrounding area of the trench 28 and the via 29. The wet etching process using a mixture containing ionized water (H₂O) and hydrofluoric acid (HF) is applied on the whole structure to remove the polymer residues 200. The etching selectivity between the passivation layer 22, the first low k dielectric layer 23, the stop layer 24 and the second dielectric layer 26 is different, a poor profile is the result for the dual damascene structure as shown in FIG. 2D. Therefore, the dual damascene process encounters the same problems existing in the single damascene process.

Accordingly, it is an intention to provide a method for improving damascene profile, which can overcome the drawback of the prior art and facilitate quality control of semiconductor devices.

### SUMMARY OF THE INVENTION

It is an objective of the present invention to provide a method for forming a uniform damascene profile, which applies a wet etching process with a mixture containing ionized water, hydrochloric acid and hydrofluoric acid on a damascene structure to improve its profile.

It is another objective of the present invention to provide a method for forming a uniform damascene profile, which is simple, convenient and inexpensive, and does not increase additional steps in a damascene process.

In order to achieve the above objectives, the present invention provides a method for forming a uniform damascene profile. A substrate with a single/dual damascene structure formed thereon is provided. A wet etching process is applied on the substrate. The wet etching process uses a mixture containing ionized water, hydrochloric acid and hydrofluoric acid as an etching solution that makes an etch selectivity between various layers, such as passivation layers, dielectric layers and stop layers, formed on the substrate, approximately 1:1. Thereby, a good damascene profile is obtained after the wet etching process.

### BRIEF DESCRIPTION OF THE DRAWINGS

The present invention can be best understood through the following description and accompanying drawings, wherein:

FIG. 1A to 1D show cross-sectional views of various steps for forming a single damascene structure in the prior art;

FIG. 2A to 2D show cross-sectional views of various steps for forming a dual damascene structure in the prior art;

FIG. 3A to 3D show cross-sectional views of various steps for forming a dual damascene structure according to the present invention; and

FIG. 4 shows a cross-sectional view of a single damascene structure provided by the present invention.

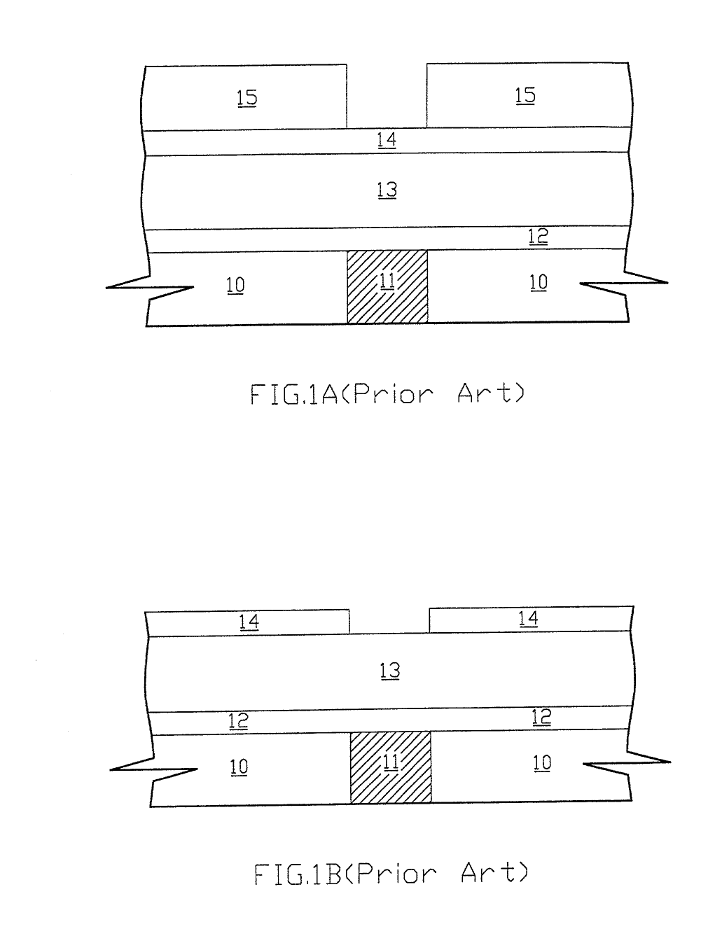

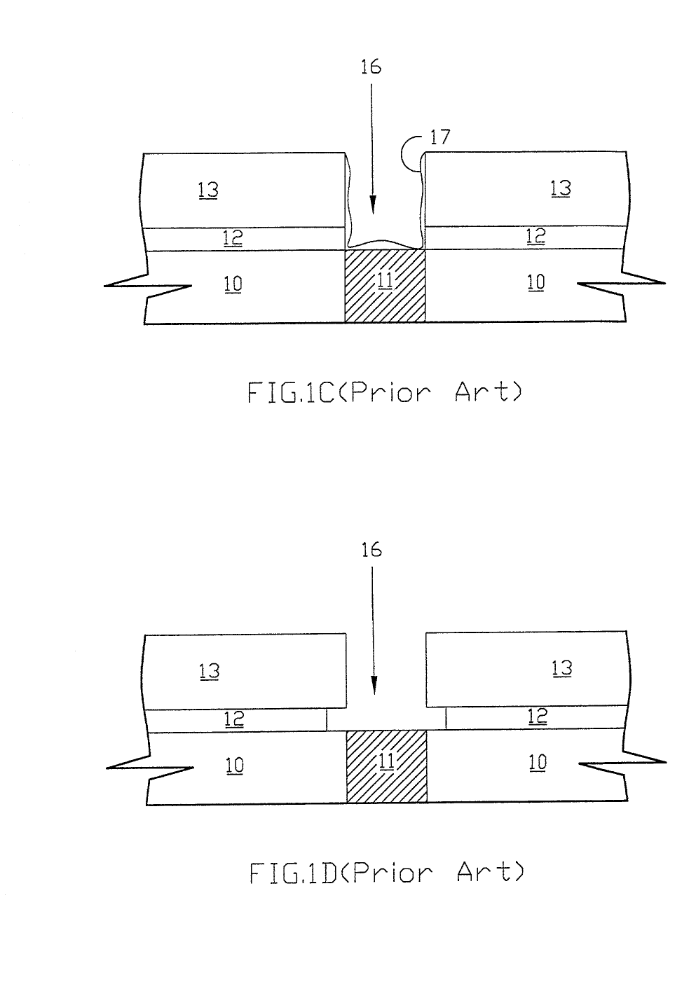

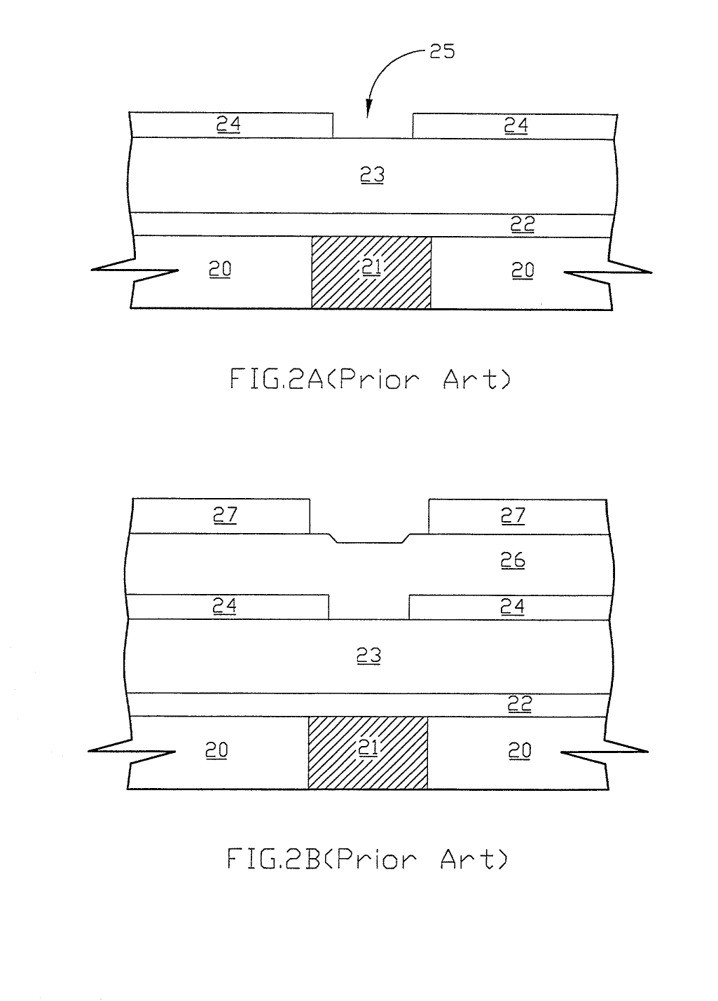

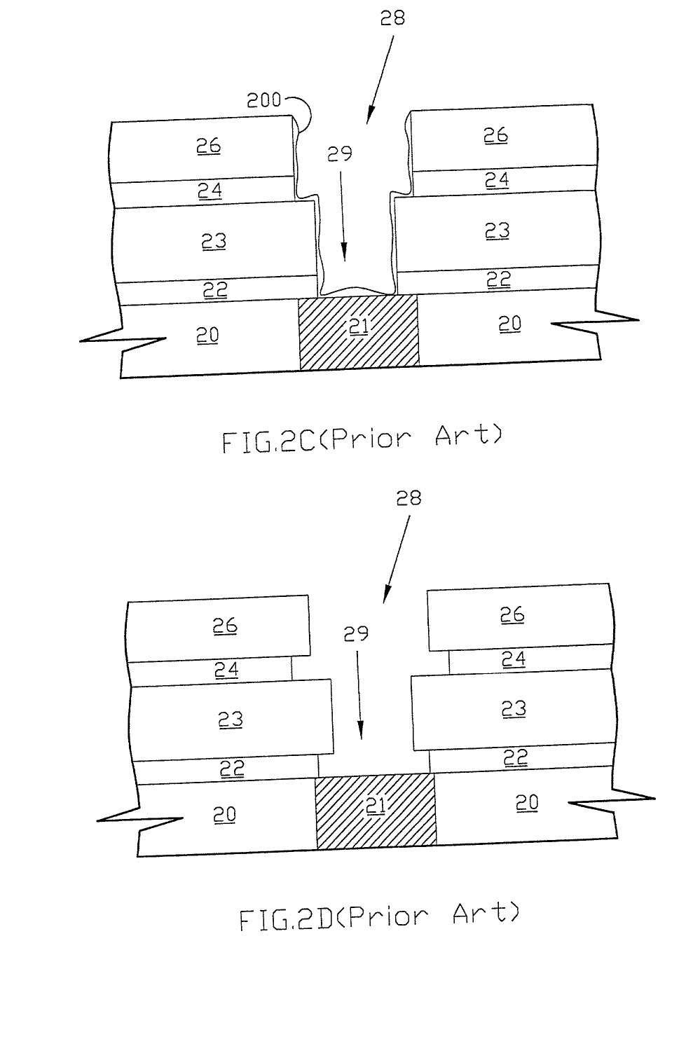

### DESCRIPTION OF THE PREFERRED EMBODIMENTS

The present invention will be described in detail with reference to the accompanying drawings. The present invention provides a method for improving a profile of a damascene structure.

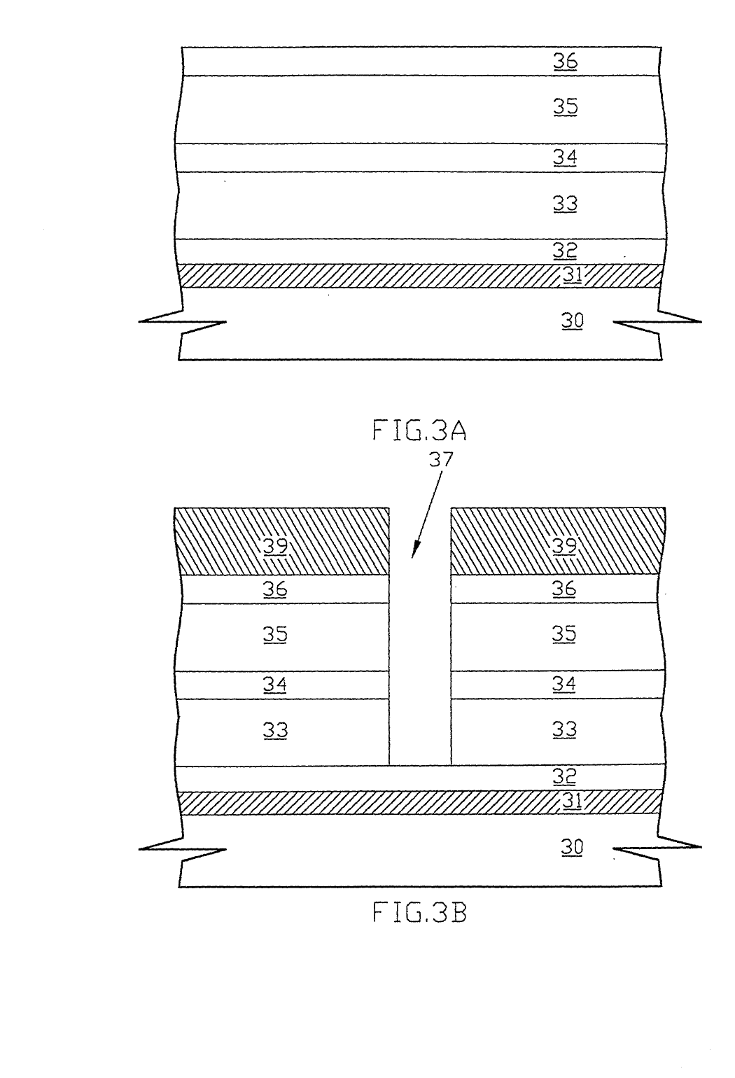

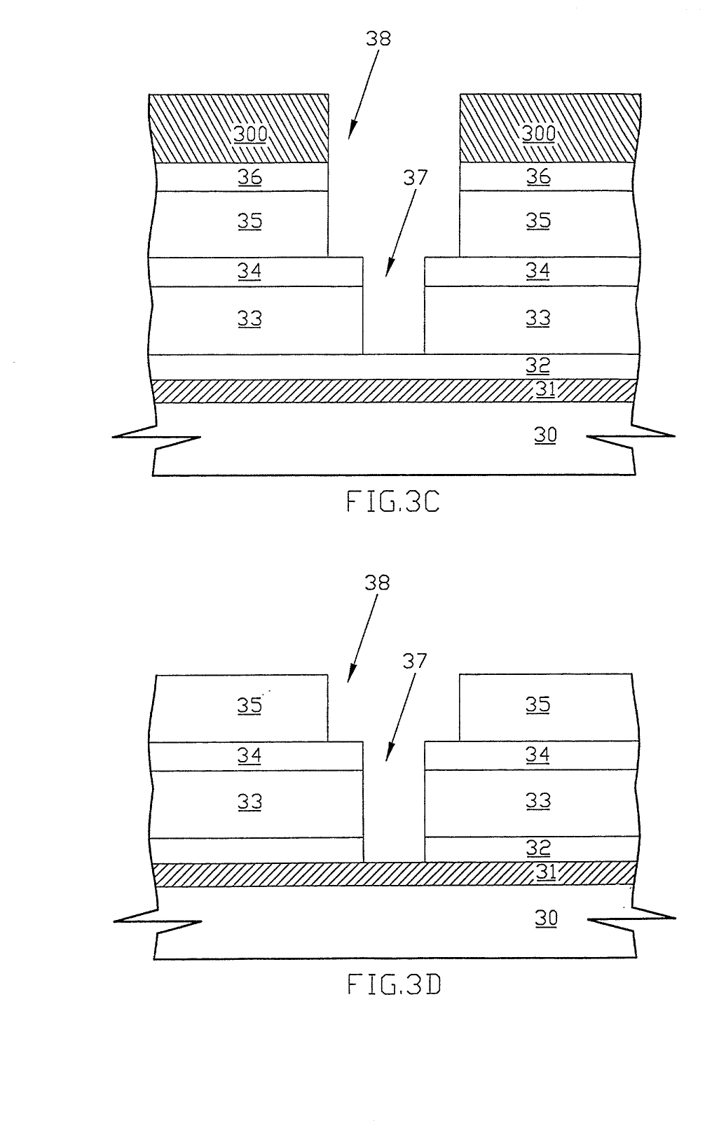

Referring to FIG. 3A, a first embodiment of the present invention begins by providing a semiconductor structure (30) having a conductive layer 31 overlying. Semiconductor structure (30) should be understood to include a substrate or wafer comprising a semiconductor material such as silicon or germanium, or a silicon-on-insulator (SOI) structure as is known in the art. Semiconductor structure (30) should be understood to possibly further include one or more layers of insulating material, dielectric material, and/or conductive material and one or more active and/or passive devices formed in or over the substrate or the like. The conductive layer 31 can comprise a metal, most preferably copper, or any other conductive material such as doped silicon. Typically, the conductive layer 31 is an interconnect pattern or line.

Still referring to FIG. 3A, a passivation layer 32 is formed on the conductive layer 31. The passivation layer 32 can comprise plasma enhanced nitride or silicon nitride. A first dielectric layer 33 is formed over the passivation layer 32. The first dielectric layer 33 can comprise an inorganic low k material, such as silicon dioxide, hydrogen-doped silicon dioxide, fluorine-doped silicon dioxide and carbon-doped silicon dioxide, or a low k organic polymer comprising carbon and hydrogen.

Still referring to FIG. 3A, a stop layer 34 is formed over the first dielectric layer 33. The stop layer 34 can comprise silicon nitride or plasma enhanced nitride. A second dielectric layer 35 is formed over the stop layer 34. The second dielectric layer 35 can comprise an inorganic low k material, such as silicon dioxide, hydrogen-doped silicon dioxide, fluorine-doped silicon dioxide and carbon-doped silicon dioxide, or a low k organic polymer comprising carbon and hydrogen. A cap layer 36 can be optionally formed over the second dielectric layer 35. The cap layer can comprise silicon nitride.

Referring to FIG. 3B and 3C, the cap layer 36, the second dielectric layer 35, the stop layer 34 and the first dielectric layer 33 are patterned to form a via 37 stopping on the passivation layer 32 and a trench 38 stopping on the stop layer 34. The patterning can be performed using any of a number of methods known in the art.

For example, as shown in FIG. 3B, a first photoresist mask 39 having an opening over the intended location for a via can be formed over the cap layer 36. The cap layer 36, the second dielectric layer 35, the stop layer 34 and the first dielectric layer 33 are etched through the opening in the first photoresist mask 39 to form the via 37, and the first photoresist mask 39 is removed.

The cap layer 36 comprising silicon nitride can be etched using a conventional fluorine-based plasma etch process. The second dielectric layer 35 comprising an organic low k material can be etched with anoxygen-containing plasma. Alternately, the second dielectric layer 35 comprising an inorganic low k material such as doped or undoped silicon dioxide can be etched with a fluorine-based reactive ion etch process chemistry. The stop layer 34 comprising plasma enhanced nitride or silicon nitride can be etched using a conventional fluorine-based plasma etch process. The first dielectric layer 33 comprising an organic low k material can be etched with an oxygen-containing plasma. Alternately, the first dielectric layer 33 comprising an inorganic low k material such as doped or undoped silicon dioxide can be etched with a fluorine-based reactive ion etch process chemistry.

As shown in FIG. 3C, a second photoresist mask 300 having an opening over the intended location for a trench can be formed over the cap layer 36. The cap layer 36 exposed through the opening in the second photoresist mask 300 is etched using the etch process as described above. Then, the trench 38 is etched in the second dielectric layer 35 using the etch process as described above, stopping on the stop layer 34. The second photoresist mask 300 is removed. The cap layer 36 is then removed by the etch process as described above. Before or after the second photoresist mask 300 is removed, the portion of the passivation layer 32 exposed through the trench 38 and the via 37 is removed by the etch process as described above. A resulting dual damascene structure is shown in FIG. 3D. However, the stop layer 34 can be optional (i.e. omitted), and the second dielectric layer 35 and the first dielectric layer 33 become one dielectric layer. The etch step for forming the trench 38 in the dielectric layer can be performed using a timed or endpoint etch process.

As described in the technical background, during various etching processes for forming the dual damascene structure, there are polymer residues produced and left on the surrounding area of the via 37 and the trench 38. The present invention develops a wet etching process using a mixture containing ionized water (H2O), hydrochloric acid (HC1) and hydrofluoric acid (HF) as an etching solution to apply on the dual damascene structure to remove the polymer residues. The etching solution of the mixture of ionized water, hydrochloric acid and hydrofluoric acid makes an etch selectivity between the passivation layer 32, the first dielectric layer 33, the stop layer 34 and the second dielectric layer 35 approximately 1:1. A preferable volume proportion of ionized water, hydrochloric acid and hydrofluoric acid in the mixture is approximately 3000˜100:100˜0:1. A dual damascene profile can be obtained using the wet etching process to remove polymer residues, no matter how long the wet etching process takes.

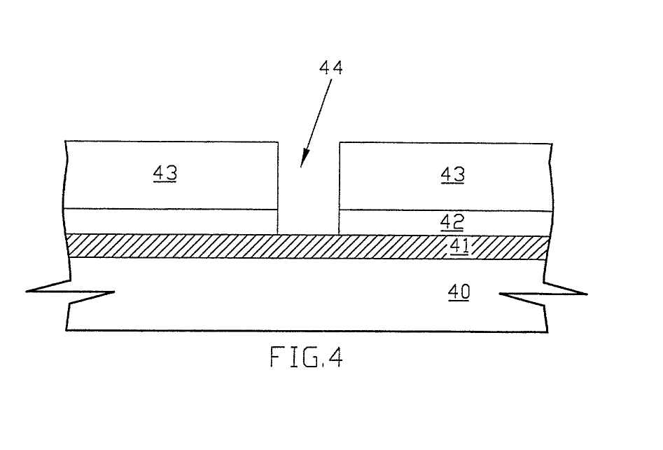

FIG. 4 shows an alternate damascene structure provided in the present invention. A single damascene structure can be formed using only one dielectric layer and a single damascene opening. A passivation layer 42 is formed on a conductive layer 41 overlying a semiconductor structure 40. A dielectric layer 43 is formed on the passivation layer 42. An optional cap layer (not shown) can be formed on the dielectric layer 43. The optional cap layer and the dielectric layer 43 are patterned to form a damascene opening 44. Then, the portion of the passivation layer 42 exposed through the damascene opening 44 is etched, resulting in the single damascene structure of FIG. 4. The optional cap layer, the dielectric layer 43 and the passivation layer 42 can be formed from the materials described above and etched by the above described etching processes. The etching solution of the mixture of ionized water, hydrochloric acid and hydrofluoric acid, preferably in the volume proportion of approximately 3000˜100:100˜0:1, is then applied on the single damascene structure to remove polymer residues left on the surrounding area of the damascene opening 44. A good single damascene profile is obtained after applying the etching solution.

Although the present etching solution is applied on the single/dual damascene structure provided by the present invention. The present etching solution can also be applied on the damascene structures formed by other damascene processes to obtain good profiles thereof.

The embodiments are only used to illustrate the present invention, not intended to limit the scope thereof. Many modifications of the preferred embodiments can be made without departing from the spirit of the present invention.

What is claimed is:

1. A method for forming a uniform damascene profile, comprising:
providing a substrate with a single damascene structure formed thereon, said single damascene structure having a passivation layer and a dielectric layer in sequence formed on said substrate and a via hole penetrating through said dielectric layer and said passivation layer; and
applying a wet etching process with a mixture containing ionized water (H₂O), hydrochloric acid (HCl) and hydrofluoric acid (HF) as an etching solution on said substrate.

2. The method of claim 1, wherein said substrate further comprises an interconnection layer underlying said single damascene structure.

3. The method of claim 1, wherein said passivation layer comprises plasma enhanced nitride.

4. The method of claim 1, wherein said passivation layer comprises silicon nitride.

5. The method of claim 1, wherein said dielectric layer comprises an organic low-K dielectric material.

6. The method of claim 1, wherein said dielectric layer comprises an inorganic low-K dielectric material.

7. The method of claim 1, wherein a volume proportion of ionized water, hydrochloric acid and hydrofluoric acid in said mixture is approximately 3000˜100:100˜0:1 in volume.

8. A method for forming a uniform damascene profile, comprising:
providing a substrate with a dual damascene structure formed thereon, said dual damascene structure comprising a passivation layer and a first dielectric layer in sequence formed on said substrate, a trench formed in an upper portion of said first dielectric layer and a via hole communicating with said trench and penetrating through a lower portion of said first dielectric layer and said passivation layer; and
applying a wet etching process with a mixture containing ionized water, hydrochloric acid and hydrofluoric acid as an etching solution on said substrate.

9. The method of claim 8, wherein said substrate further comprises an interconnection layer underlying said dual damascene structure.

10. The method of claim 8, wherein said passivation layer comprises plasma enhanced nitride.

11. The method of claim 8, wherein said passivation layer comprises silicon nitride.

12. The method of claim 8, wherein said dielectric layer comprises an organic low-K dielectric material.

13. The method of claim 8, wherein said dielectric layer comprises an inorganic low-K dielectric material.

14. The method of claim 8, wherein a volume proportion of ionized water, hydrochloric acid and hydrofluoric acid in said mixture is approximately 3000˜100:100˜0:1.

15. A method for forming a uniform damascene profile, comprising:
providing a substrate with a dual damascene structure formed thereon, said dual damascene structure comprising a passivation layer, a first dielectric layer, a stop layer and a second dielectric layer in sequence formed on said substrate, a trench formed in said second dielectric layer over said stop layer and a via hole communicating with said trench and penetrating through said stop layer, said first dielectric layer and said passivation layer; and
applying a wet etching process with a mixture containing ionized water, hydrochloric acid and hydrofluoric acid as an etching solution on said substrate.

16. The method of claim 15, wherein said substrate further comprises an interconnection layer underlying said dual damascene structure.

17. The method of claim 15, wherein said passivation layer comprises plasma enhanced nitride.

18. The method of claim 15, wherein said passivation layer comprises silicon nitride.

19. The method of claim 15, wherein said first dielectric layer comprises an organic low-K dielectric material.

20. The method of claim 15, wherein said first dielectric layer comprises an inorganic low-K dielectric material.

21. The method of claim 15, wherein said stop layer comprises plasma enhanced nitride.

22. The method of claim 15, wherein said stop layer comprises silicon nitride.

23. The method of claim 15, wherein said second dielectric layer comprises an organic low-K dielectric material.

24. The method of claim 15, wherein said second dielectric layer comprises an inorganic low-K dielectric material.

25. The method of claim 15, wherein a volume proportion of ionized water, hydrochloric acid and hydrofluoric acid in said mixture is approximately 3000˜100:100˜0:1.
